(19) United States
(12) Patent Application Publication
(10) Pub. No.: US 2008/0101046 A1
(43) Pub. Date: May 1, 2008

(54) Motherboard

(75) Inventor: Yu-Chen Lee, Taipei (TW)

Correspondence Address: BACON & THOMAS, PLLC, 625 SLATERS LANE, FOURTH FLOOR, ALEXANDRIA, VA, 22314, US

(73) Assignee: ASUSTek COMPUTER INC., Taipei (TW)

(21) Appl. No.: 11/907,645

(22) Filed: Oct. 16, 2007

(30) Foreign Application Priority Data
Oct. 31, 2006 (TW) 95140320

(51) Int. Cl. H05K 7/12

(52) U.S. Cl. 361/767

(57) ABSTRACT

A motherboard for computer is disclosed. The motherboard includes a printed circuit board (PCB), a first slot, a second slot, and a control unit. The first slot, the second slot, and the control unit are disposed on the PCB. The first slot is for receiving-a first double data rate (DDR) memory module. The second slot electrically connected to the first slot is used for selectively receiving a second DDR memory module or a daughter card having a plurality of terminal resistors. The control unit is electrically connected to the first slot and the second slot. When the first slot receives the first DDR memory module, and the second slot receives the daughter card, the control unit can transmit data to the first DDR memory module by using the daughter card.

This application claims the benefit of Taiwan application Serial No. 95140320, filed Oct. 31, 2006, the subject matter of which is incorporated herein by reference.

### BACKGROUND OF THE INVENTION

1. Field of the Invention

The invention relates to a motherboard and, more particularly, to a motherboard that can support two kinds of memory modules, the second generation double data rate (DDR2) synchronous dynamic random access memory module and the third generation double data rate (DDR3) synchronous dynamic random access memory module.

2. Description of the Related Art

The double data rate (DDR) technology arose after the synchronous dynamic random access memory (SDRAM) technology, and has been matured from the first generation double data rate (DDR1) technology into the second-generation double data rate (DDR2) technology. DDR1 has the standard working frequency of 400 MHz and the pre-fetch of 2 bits, while DDR2, doubling the rate of data transmission of DDR1, has the working frequency of 400˜1066 MHz and the pre-fetch of 4 bits.

Generally speaking, when the newer generation memory module, such as DDR2 memory module, just come onto the market, motherboard manufacturers usually provide the motherboards that can support two kinds of memory modules to meet the market demand at that moment since many users still use old memory module, such as DDR1 memory module.

FIG. 1 is a schematic diagram showing a motherboard that can support DDR1 and DDR2 memory modules. In FIG. 1, a central processing unit (CPU) 110, a north bridge chip 120, a south bridge chip 130, a peripheral component interconnect (PCI) slot 140, a DDR1 memory module slot s1, and a DDR2 memory module slot s2 are disposed on the motherboard 100.

The CPU 110 is connected to the north bridge chip 120 through a front side bus (FSB). The he north bridge chip 120 can be connected to at least one memory and a video card. Likewise, the south bridge chip 130 can be connected to peripheral devices, such as a disk drive or an optical disc drive.

In FIG. 1, the north bridge chip 120 is connected to the DDR1 memory module slot s1 and the DDR2 memory module slot s2, wherein a plurality of terminal resistors r are provided beside the DDR1 memory module slots s1 and DDR2 memory module s2. Since the DDR2 memory module has a built-in signal on-die termination (ODT), the terminal resistors are beside the DDR2 memory module slot s2 are fewer than those beside the DDR1 memory module slot s1.

When a DDR1 (DDR2) memory module is inserted into the corresponding slot s1 (s2) for data transmission, the terminal resistors r electrically connected to the slot s1 (s2) are used to make an impedance match with the transmission path between the memory module and the motherboard 100 to reduce the reflected signal interference and to avoid the transmission errors of some signals, such as data signals, control signals, address signals, command signals, and so on. Thereby, during the technology transition, consumers can have more selections and expansion flexibility.

However, when the new generation of DDR technology with greater speed and efficiency is sought continuously (for example, DDR3 memory, whose working frequency is 800-1600 MHz (in the future it may be higher) and whose pre-fetch is 8 bits), providing motherboards both supporting the new generation DDR memory and meanwhile being compatible with DDR2 downward may be a demand for future market.

### SUMMARY OF THE INVENTION

Base on the above, the objective of the invention is to provide a motherboard that can support two kinds of memory modules, the second generation double data rate (DDR2) synchronous dynamic random access memory module and the third generation double data rate (DDR3) synchronous dynamic random access memory module. The motherboard according to the invention uses a daughter card to improve the problem of compatibility of DDR2 memory modules to allow users to select DDR2 or DDR3 memory module according to their needs.

To achieve the above objective, the invention provides a motherboard including a printed circuit board (PCB), a first slot, a second slot and a control unit. The first slot, the second slot, and the control unit are disposed on the PCB. The first slot is used for receiving a first DDR memory module. The second slot electrically connected to the first slot is used for selectively receiving a second DDR memory module or a daughter card having a plurality of terminal resistors. The control unit is electrically connected to the first slot and the second slot. When the first slot receives the first DDR memory module and the second slot receives the daughter card, the control unit can transmit data to the first DDR memory module by using the daughter card.

To achieve the above objective, the invention provides a motherboard capable of receiving a daughter card having a plurality of terminal resistors. The motherboard includes a PCB, a first slot and a second slot, wherein the first slot and the second slot are disposed on the PCB. The first slot is used for receiving a second-generation double data rate (DDR2) synchronous dynamic random access memory module. The second slot, electrically connected to the first slot, is used for selectively receiving a third generation double data rate (DDR3) synchronous dynamic random access memory module or a daughter card.

The invention uses a daughter card to satisfy the different needs of the number of the terminal resistors for different DDR memory modules on a motherboard, so that two kinds of DDR memory modules, such as DDR2 memory module and DDR3 memory module, can be supported. Thereby, during the technology transition, it provides further selectivity and installation flexibility to the consumers.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a conventional motherboard that can support DDR1 and DDR2 memory modules.

FIG. 2 is a schematic diagram showing a motherboard according to an embodiment of the invention.

FIG. 3A is a schematic diagram showing a motherboard using a first double data rate (DDR) memory module D1 according to an embodiment of the invention.

FIG. 3B is a schematic diagram showing a motherboard using a second DDR memory module D2 according to an embodiment of the invention.

FIG. 4 is a schematic diagram showing that a control unit is electrically connected to a first slot and a second slot directly on a motherboard according to another embodiment of the invention.

### DETAILED DESCRIPTION OF THE INVENTION

As mentioned above, terminal resistors are needed to be installed on the motherboard for the slots corresponding to DDR1 and DDR2 memory modules. However, since the technology of the third generation double data rate (DDR3) synchronous dynamic random access memory (SDRAM) completely packages terminal resistors into memory modules, no terminal resistors are needed to be installed on the motherboard. In view of this difference, a preferred embodiment of the invention provides a motherboard that can support two kinds of DDR memory modules, such as DDR2 memory module and DDR3 memory module. When the DDR2 memory module is used, no problem of signal transmission due to the absence of the terminal resistors exists on the motherboard.

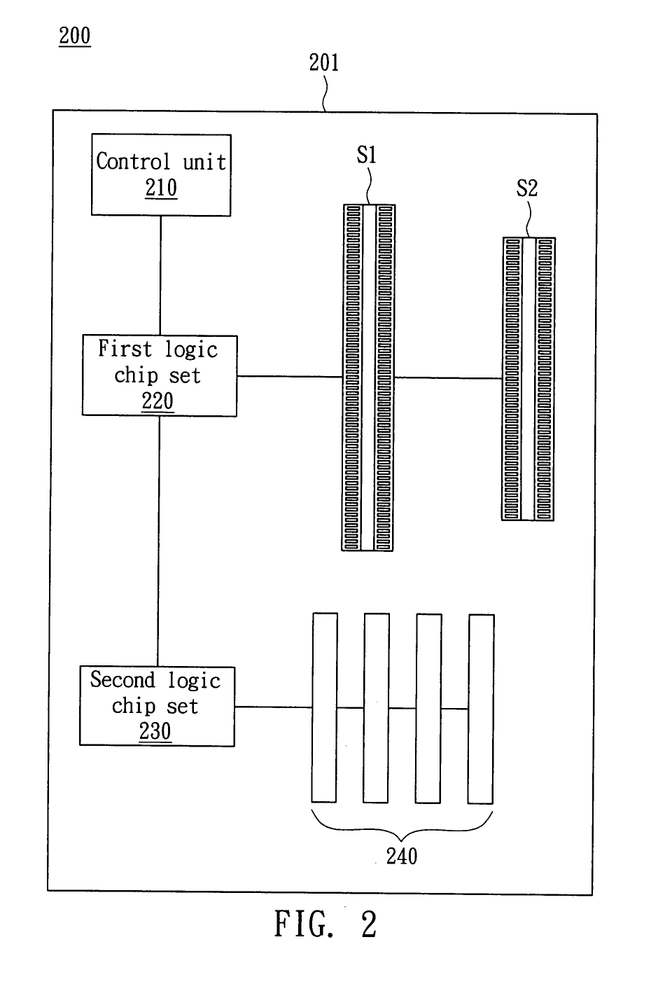

Please refer to FIG. 2, which is a schematic diagram showing a motherboard according to a preferred embodiment of the invention. The motherboard 200 includes a printed circuit board (PCB) 201. It also includes a control unit 210, a first logic chip set 220, a second logic chip set 230, a first slot S1, and a second slot S2, all of which are disposed on the PCB 201.

The first slot S1 is electrically connected to the second slot S2, and the control unit 210 is electrically connected to the first slot S1 and the second slot S2, respectively. In FIG. 2, the control unit 210 is electrically connected to the first slot S1 and the second slot S2 by the first logic chip set 220. Of course, in other embodiments, the control unit 210 may also be electrically connected to the first slot S1 and the second slot S2 directly.

In this embodiment, the first logic chip set 220 is a north bridge chip, and the second logic chip set 230 is a south bridge chip. In this embodiment, the first slot S1 can receive a first DDR memory module, and the second slot S2 can selectively receive a second DDR memory module or a daughter card, wherein the first DDR memory module is, for example, a DDR2 memory module which has the pre-fetch of 4 bits, and the second DDR memory module is, for example, a DDR3 memory module which has the pre-fetch of 8 bits.

In addition, the first DDR memory module and the second DDR memory module, for example, are dual in-line memory modules (DIMM), while the first slot S1 and the second slot S2 also respectively use the DIMM packaging specifications corresponding the DDR2 memory module and the DDR3 memory module to prevent the memory modules being inserted into the wrong slots by mistake. That is, the first slot S1 and the second slot S2 may have different numbers of plug jacks and the positions of the plug jacks may also be different. In addition, in this embodiment, the daughter card has a plurality of terminal resistors and can be inserted into the second slot S2, wherein the terminal resistors of the daughter card can make the impedance match with the first DDR memory module (DDR2 memory module).

Of course, in other embodiments, the first DDR memory module D1 and the second DDR memory module D2 can also be other new generation DDR memory modules, and some corresponding resistors and relative circuits will be disposed on the daughter card.

An embodiment will be described herein below, and in the embodiment, the first slot S1 on the motherboard 200 receives a DDR2 memory module, or the second slot S2 on the motherboard 200 receives a DDR3 memory module.

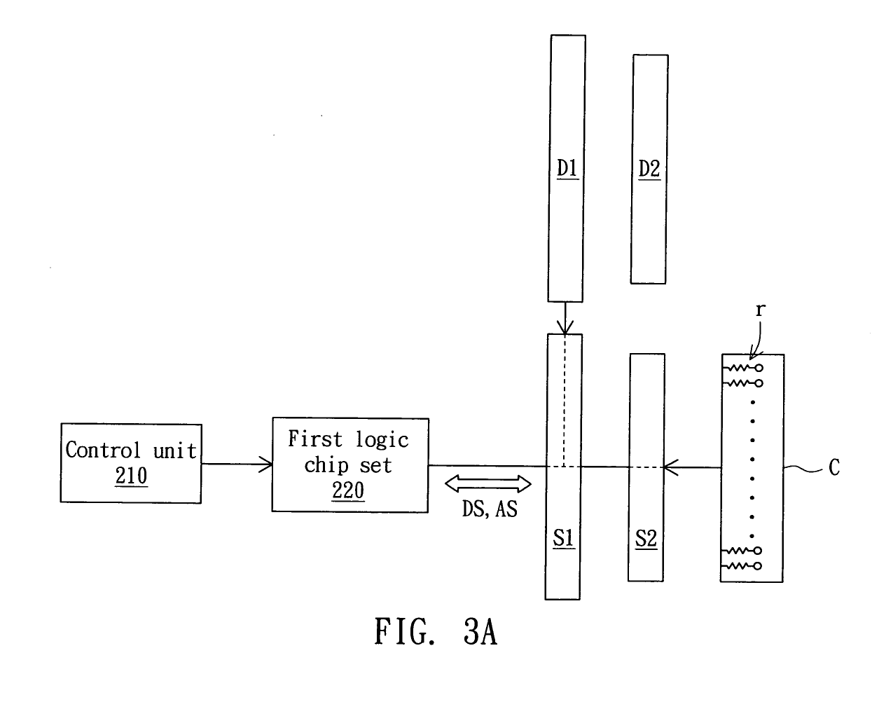

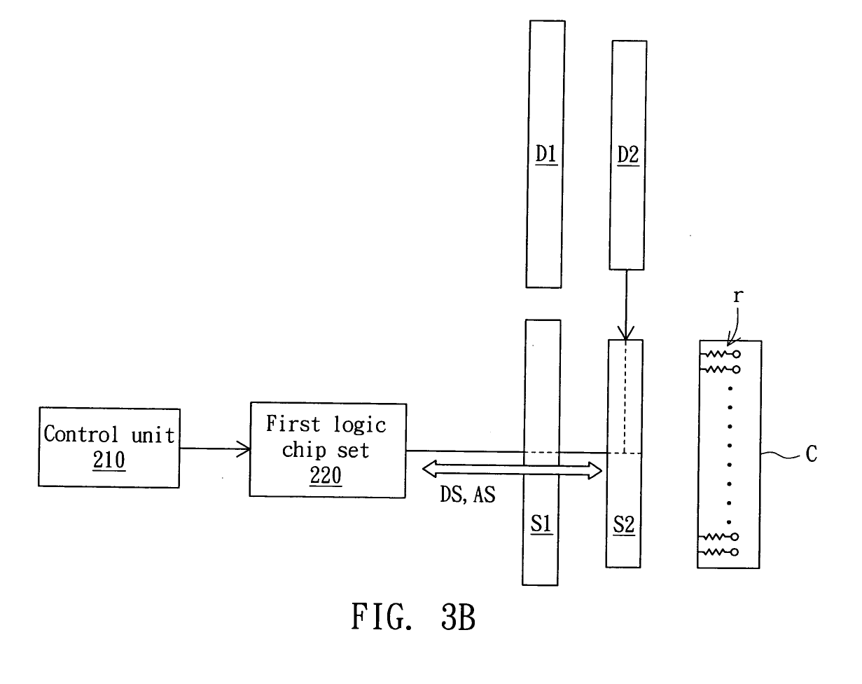

Please refer to FIG. 3A and FIG. 3B, wherein FIG. 3A is a schematic diagram showing a motherboard using a first DDR memory module D1 according to a preferred embodiment of the invention, and FIG. 3B is a schematic diagram showing a motherboard using a second DDR memory module D2 according to a preferred embodiment of the invention.

As shown in FIG. 3A, when the motherboard uses the first DDR memory module D1 such as a DDR2 memory module, and the first slot S1 receives the first DDR memory module D1, the second slot S2 needs to receive a daughter card C to achieve the impedance matching since no terminal resistors r are assembled beside the first slot S1 and the second slot S2 in the embodiment.

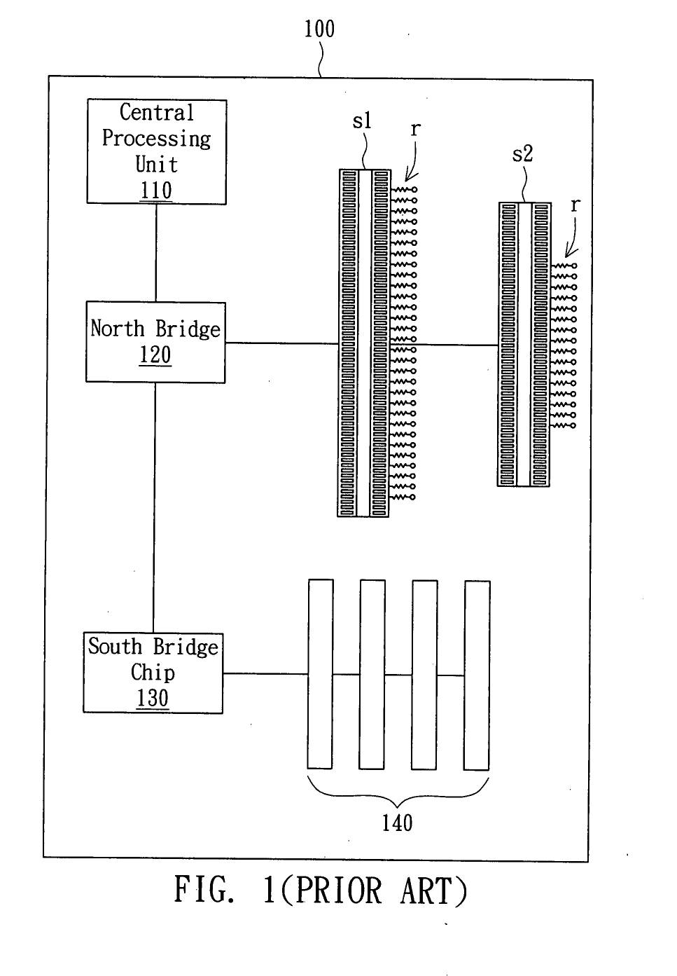

That is to say, by the electrical connection between the second slot S2 and the first slot S1, a plurality of the terminal resistors r of the daughter card C can realize the same result as that of the terminal resistors besides the slot in FIG. 1 for the first DDR memory module D1 inserted into the first slot S1. Thereby, when the control unit 210 controls the first logic chip set 220 to transmit data to the first DDR memory module D1, the normal operation of the first DDR memory module D1 and the integrity of the related signals, such as Data Signal (DS), Address Signal (AS), and so on can be ensured.

Next, please refer to FIG. 3B. When the motherboard 200 uses the second DDR memory module D2, such as DDR3 memory module, what is needed to do is just to insert the second DDR memory module D2 into the second slot S2. Of course, now the first DDR memory module D1 and the daughter card C are removed.

Now, the control unit 210 can control the first logic chip set 220 to transmit data to the second DDR memory module D2, while the second DDR memory module D2 using a DDR3 chip, as explained above, can operate normally without additional terminal resistors. Therefore, the motherboard 200 can support two kinds of DDR memory modules such as DDR2 memory module and DDR3 memory module and provide users excellent installation flexibility.

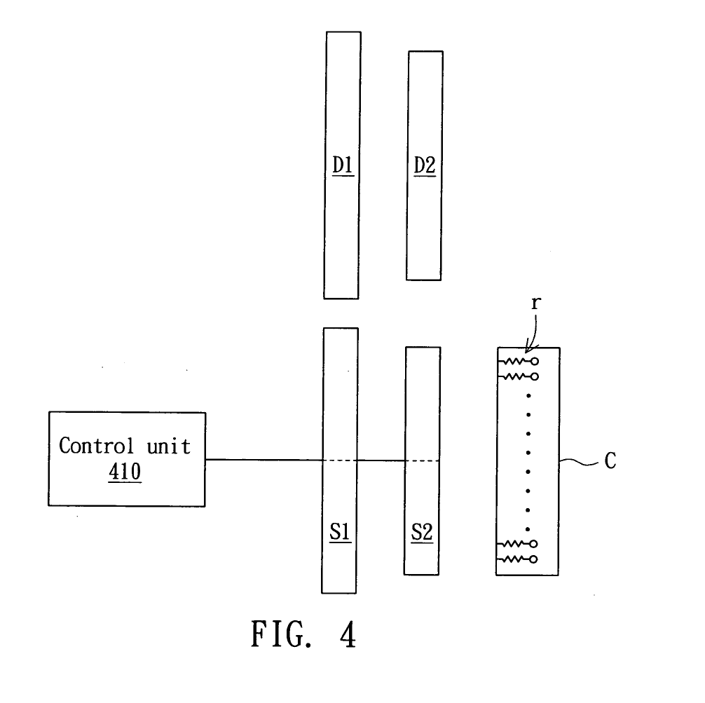

Of course, persons having ordinary skill in the art of the invention can also understand that the technology of the invention is not limited to the embodiments above. For example, now, with a CPU integrated with a memory controller, the CPU disposed on the motherboard can be directly connected to a memory slot to transmit data with a memory module. As shown in FIG. 4, a control unit 410 with a memory controller built-in can be electrically connected to the slots S1 and S2 directly and can transmit data with the DDR memory modules D1 and D2 according to the needs of users as shown in FIGS. 3A and 3B. Moreover, the number of the two kinds of slots on the motherboard is not limited to the embodiments. For example, in view of the output port of the north bridge chip and other related designs on the motherboard, there are the following compositions: four slots corresponding to DDR2 matching with two slots corresponding to DDR3, or two slots corresponding to DDR2 matching with a slot corresponding to DDR3, and the number of daughter cards can be adjusted according to the connection relationship of the two kinds of slots. In addition, the daughter cards can also be manufactured and sold together with the motherboard. It does not depart from the technical scope of the invention as long as a daughter card with terminal resistors is used to make a motherboard support two kinds of DDR memory modules, such as DDR2 memory module and DDR3 memory module.

The motherboards disclosed in the above embodiments use a daughter card to satisfy the different needs of two different DDR memory modules for the number of the terminal resistors on a motherboard, so that two kinds of DDR memory modules, such as DDR2 memory module and DDR3 memory module, can be supported. Thereby, during the technology transition, it provides further selectivity and installation flexibility to the consumers.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A motherboard comprising:
a printed circuit board (PCB);
a first slot disposed on the PCB and used for receiving a first double data rate (DDR) memory module;
a second slot disposed on the PCB, electrically connected to the first slot and used for selectively receiving a second DDR memory module or a daughter card having a plurality of terminal resistors; and
a control unit disposed on the PCB and electrically connected to the first slot and the second slot;
wherein when the first slot receives the first DDR memory module, and the second slot receives the daughter card, the control unit can transmit data to the first DDR memory module by using the daughter card.

2. The motherboard according to claim 1, wherein when the second slot receives the second DDR memory module, the control unit can directly transmit data to the second DDR memory module.

3. The motherboard according to claim 1 further comprising a logic chip set, so that the control unit electrically connected to the first slot and the second slot through the logic chip set.

4. The motherboard according to claim 3, wherein the logic chip set is a north bridge chip.

5. The motherboard according to claim 1, wherein the control unit is electrically connected to the first slot and the second slot directly.

6. The motherboard according to claim 1, wherein the control unit is a central processing unit (CPU).

7. The motherboard according to claim 1, wherein the first DDR memory module is a second-generation double data rate (DDR2) synchronous dynamic random access memory.

8. The motherboard according to claim 1, wherein the second DDR memory module is a third generation double data rate (DDR3) synchronous dynamic random access memory.

9. A motherboard capable of receiving a daughter card having a plurality of terminal resistors, the motherboard comprising:
a printed circuit board (PCB);
a first slot disposed on the PCB and used for receiving a second generation double data rate (DDR2) synchronous dynamic random access memory (SDRM) module; and
a second slot disposed on the PCB and electrically connected to the first slot and used for selectively receiving a third generation double data rate (DDR3) synchronous dynamic random access memory module or the daughter card.

10. The motherboard according to claim 9 further comprising a control unit disposed on the PCB and electrically connected to the first slot and the second slot, wherein when the first slot receives the second generation double data rate (DDR2) synchronous dynamic random access memory, and the second slot receives the daughter card, the control unit can transmit data to the DDR2 SDRM module by using the daughter card.
